(19) United States
(12) Patent Application Publication
(10) Pub. No.: US 2007/0261819 A1
(43) Pub. Date: Nov. 15, 2007

(54) HEAT DISSIPATING DEVICE

(75) Inventor: MONG-TUNG LIN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,749

(22) Filed: Sep. 21, 2006

(30) Foreign Application Priority Data
Dec. 9, 2005 (CN) 200510102313.9

(51) Int. Cl. H05K 7/20

(52) U.S. Cl. 165/80.4; 361/699

(57) ABSTRACT

The heat dissipating device (100) includes a container (110), a number of fins (120) and a cooling liquid (140). The container has a mounting portion (111) structured and arranged for mounting on a heat generating device (300). The mounting portion of the container has a shape conforming to a shape of the heat generating device. The container further includes an inlet (113) and an outlet (114). The container is comprised of a material selected from the group consisting of alumina, copper, stainless steel and any combination alloy thereof. The fins are arranged in the container and extending from the mounting portion thereof. The heat dissipating device further includes a thermal interface material (130) configured for being sandwiched between the mounting portion of the container and the heat generating device.

### FIELD OF THE INVENTION

The invention relates generally to heat dissipating devices and, more particularly, to a heat dissipating device using a cooling liquid to cool electronic components.

### DESCRIPTION OF RELATED ART

The performance of electronic devices is limited by their working temperature. Performance degrades when the internal temperature reaches or exceeds a particular limit. In order to maintain or increase the performance of such devices, one known cooling technique is to attach a heat sink with fins to the electronic device. The heat sink draws heat away from the electronic device and can be air cooled or liquid cooled, depending upon the particular application.

Referring to FIG. 3, a conventional example of heat dissipating device 200 includes a fluid container 210, a cooling fluid 220, a first thermal gasket 230, a device casing 240 and a second thermal gasket 250. The fluid container 210 further includes an inlet 211 and an outlet 212. The cooling liquid 220 flows into the fluid container 210 via the inlet 211, absorbs heat generated from the device casing 240 and then flows out via the outlet 212. Different cooling fluids may be used depending upon the application and the density of electronic devices in a given circuit, for example, water and fluorinated hydrocarbon refrigerants can be used.

The device casing 240 is used to connect with an electronic device 300 and absorb the heat generated from the electronic device 300. The first thermal gasket 230 is placed between the fluid container 210 and the device casing 240 for reducing thermal resistance. The second thermal gasket 250 is placed between the device casing 240 and the electronic device 300 for reducing thermal resistance. The above heat dissipating device 200 has the problem of having a large number of components that increases thermal resistance between components. In addition, a large number of components also means high production cost.

What is needed, therefore, is a heat dissipating device has good heat dissipation ability and a simple structure.

### SUMMARY OF THE INVENTION

A heat dissipating device is provided. In one embodiment, the heat dissipating device includes a container, a number of fins and a cooling liquid. The container has a mounting portion configured (i.e., structured and arranged) for mounting on a heat generating device. The mounting portion of the container has a shape conforming to a shape of the heat generating device. The container further includes an inlet and an outlet. The container is comprised of a material selected from the group consisting of alumina, copper, stainless steel and any combination alloy thereof. The fins are arranged in the container and extending from the mounting portion thereof. The fins are surrounded by the cooling fluid. The heat dissipating device further includes a thermal interface material configured for being sandwiched between the mounting portion of the container and the heat generating device.

Advantages and novel features of the present heat dissipating device will become more apparent from the following detailed description of preferred embodiments when taken in conjunction with the accompanying drawings.

### BRIEF DESCRIPTION OF THE DRAWINGS

Many aspects of the present heat dissipating device can be better understood with reference to the following drawings. The components in the drawings are not necessarily drawn to scale, the emphasis instead being placed upon clearly illustrating the principles of the present invention.

FIG. 1 is a schematic, cross-sectional view of a heat dissipating device in accordance with a preferred embodiment;

FIG. 2 is a schematic, cross-sectional view of the heat dissipating device, taken along line III-III of FIG. 1; and

FIG. 3 is a schematic, cross-sectional view of a conventional heat dissipating device.

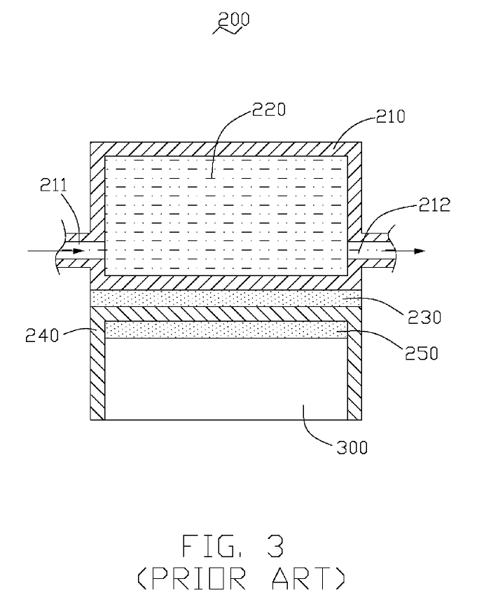

Corresponding reference characters indicate corresponding parts throughout the several views. The exemplifications set out herein illustrate at least one preferred embodiment of the present heat dissipating device, in one form, and such exemplifications are not to be construed as limiting the scope of the invention in any manner.

### DETAILED DESCRIPTION OF THE INVENTION

Reference will now be made to the drawings to describe embodiments of the present heat dissipating device in detail.

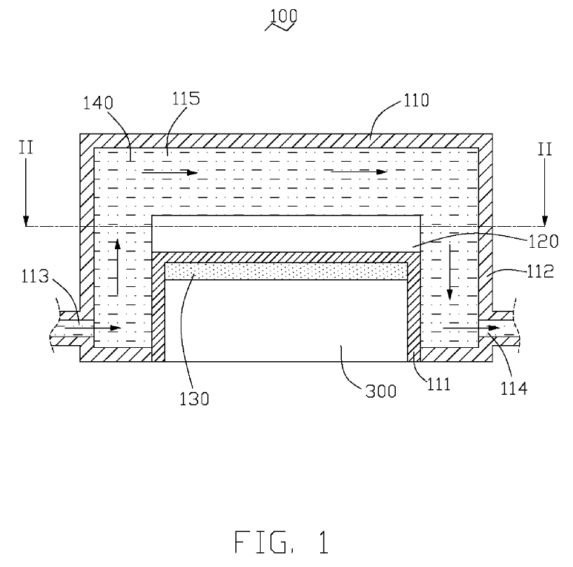

Referring to FIG. 1, a heat dissipating device 100 according to a preferred embodiment is shown. The heat dissipating device 100 includes a container 110, a number of fins 120 and a cooling liquid 140. The container 110 has a mounting portion 111 and a shell portion 112. The mounting portion 111 is structured and arranged for mounting on a heat generating device 300. The mounting portion 111 is an inwardly depressed portion of the container 110 and has a shape conforming to a shape of the heat generating device 300, such as CPU.

The mounting portion 111 and the shell portion 112 co-operatively define an inner space 115 for containing the cooling fluid 140 therein. The container 110 further includes an inlet 113 and an outlet 114. The inlet 113 and the outlet 114 are defined on two lateral side walls of the shell portion 112. The cooling fluid 140 flows into the container 110 via the inlet 113 and flows out from the container 110 via the outlet 114. Therefore, the cooling fluid 140 can flow freely between the mounting portion 111 and the shell portion 112 for cooling the heat generating device 300.

The container 110 is comprised of a material selected from the group consisting of alumina, copper, stainless steel and any combination alloy thereof. The container 110 can further be comprised of a composite containing a material selected from the group consisting of carbon nanotubes, graphite fiber and diamond powder. The fluid container 110 is made by die-casting method thus allowing mass production. The fluid container 110 can also be made by electric plating method or lithographic galvanization method.

The fins 120 are arranged in the container 110 and upwardly extending from the mounting portion 111 thereof. The fins 120 extend into an inner space 115 of the container 110. The fins 120 can be comprised of a material selected from the group consisting of alumina, copper, stainless steel and any combination alloy thereof. The fins 120 can also be comprised of a composite containing a material selected from the group consisting of carbon nanotubes, graphite fiber and diamond powder.

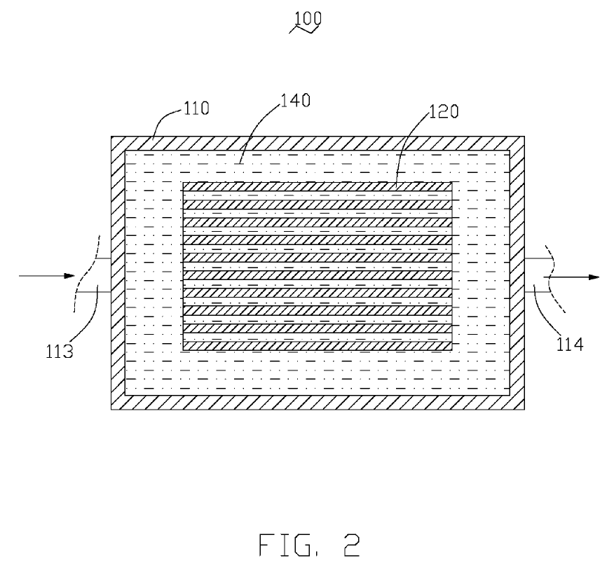

Also referring to FIG. 2, the fins 120 are separated from each other and extend along a direction substantially parallel to the flow direction of the cooling fluid 140. The cooling fluid 140 surrounds the fins 120 for heat exchange. The fins 120 can increase the heat dissipation surface area, thus improves the heat transfer rate of the heat dissipating device 100.

The cooling fluid 140 is comprised of a material selected from the group consisting of water, fluid containing heat conducting nano-particles and non-corrosive coolant, such as fluorinated hydrocarbon refrigerants. Taking the strong heat convention ability of the cooling fluid 140, the generated heat can be quickly removed from the heat generating device 300 and discharged to the environment via the heat dissipating device 100.

In order to reduce thermal resistance between the heat generating device 300 and the container 110, the heat dissipating device 100 can further include a thermal interface material 130 configured (i.e., structured and arranged) for being sandwiched between the mounting portion 111 and the heat generating device 300. In this exemplary embodiment, the thermal interface material 130 is sandwiched between the heat generating device 300 and the top surface of the mounting portion 111. Lateral sides of the heat generating device 300 may be in close contact with the side surfaces of the mounting portion 111 for further improvement of thermal contact therebetween.

The container 110 and the fins 120 are integrally formed as a single piece. This can be achieved by die casting method or other technologies, such as electric plating or lithographic galvanization. Die casting method is preferable for mass production purpose. A single piece structure can reduce the inner heat resistance of the heat dissipating device 100.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A heat dissipating device comprising:
a container having a mounting portion configured for being mounted on a heat generating device;
a cooling liquid received in the container; and
a plurality of fins arranged in the container and extending from the mounting portion thereof.

2. The heat dissipating device as claimed in claim 1, wherein the container further comprises an inlet and an outlet.

3. The heat dissipating device as claimed in claim 1, wherein the mounting portion of the container has a shape conforming to a shape of the heat generating device.

4. The heat dissipating device as claimed in claim 1, wherein the container is comprised of a material selected from the group consisting of alumina, copper, stainless steel and any combination alloy thereof.

5. The heat dissipating device as claimed in claim 3, wherein the container is further comprised of a composite containing a material selected from the group consisting of carbon nanotubes, graphite fiber and diamond powder.

6. The heat dissipating device as claimed in claim 1, further comprising a thermal interface material configured for being sandwiched between the mounting portion of the container and the heat generating device.

7. The heat dissipating device as claimed in claim 1, wherein the fins are comprised of a material selected from the group consisting of alumina, copper, stainless steel and any combination alloy thereof.

8. The heat dissipating device as claimed in claim 7, wherein the fins are further comprised of a composite containing a material selected from the group consisting of carbon nanotubes, graphite fiber and diamond powder.

9. The heat dissipating device as claimed in claim 1, wherein the mounting portion is an inwardly depressed portion of the container.

10. The heat dissipating device as claimed in claim 1, wherein the container and the fins are integrally formed as a single piece.

11. The heat dissipating device as claimed in claim 1, wherein the cooling fluid is comprised of a material selected from the group consisting of water, non-corrosive coolant and fluid with heat conducting nano-particles.
